(19) United States
(12) Patent Application Publication
(10) Pub. No.: US 2006/0169870 A1
(43) Pub. Date: Aug. 3, 2006

(54) Image sensor with embedded optical element

(76) Inventors: Christopher D. Silsby, Albany, OR (US); Homayoon Haddad, Beaverton, OR (US); Jianhong Wang, Cupertino, CA (US); William G. Gazeley, Corvallis, OR (US)

Correspondence Address: AVAGO TECHNOLOGIES, LTD., P.O. BOX 1920, DENVER, CO, 80201-1920, US

(21) Appl. No.: 11/048,180

(22) Filed: Feb. 1, 2005

(51) Int. Cl. H01L 27/00

(52) U.S. Cl. 250/208.1

(57) ABSTRACT

A pixel includes a surface configured to receive incident light and a floor formed by a semiconductor substrate. A photodetector is disposed in the floor. A dielectric structure is disposed between the surface and the floor. A volume of the dielectric structure between the surface and the photodetector provides an optical path configured to transmit a portion of the incident light upon the surface to the photodetector. An embedded optical element is disposed at least partially within the optical path and is configured to partially define the optical path.

### BACKGROUND

Imaging technology is the science of converting an image to a representative signal. Imaging systems have broad applications in many fields, including commercial, consumer, industrial, medical, defense, and scientific markets. Most image sensors are silicon-based semiconductor devices that employ an array of pixels to capture light, with each pixel including some type of photodetector (e.g., a photodiode or photogate) that converts photons incident upon the photodetector to a corresponding charge. CCD (charge coupled device) and CMOS (complementary metal oxide semiconductor) image sensors are the most widely recognized and employed types of semiconductor based image sensors.

The ability of an image sensor to produce high quality images depends on the light sensitivity of the image sensor which, in-turn, depends on the quantum efficiency (QE) and optical efficiency (OE) of its pixels. Image sensors are often specified by their QE, or by their pixel QE, which is typically defined as the efficiency of a pixel's photodetector in converting photons incident upon the photodetector to an electrical charge. A pixel's QE is generally constrained by process technology (i.e., the purity of the silicon) and the type of photodetector employed (e.g., a photodiode or photogate). Regardless of the QE of a pixel, however, for light incident upon a pixel to be converted to an electrical charge, it must reach the photodetector. With this in mind, OE, as discussed herein, refers to a pixel's efficiency in transferring photons from the pixel surface to the photodetector, and is defined as a ratio of the number of photons incident upon the photodetector to the number of photons incident upon the surface of the pixel.

At least two factors can significantly influence the OE of a pixel. First, the location of a pixel within an array with respect to any imaging optics of a host device, such as the lens system of a digital camera, can influence the pixel's OE since it affects the angles at which light will be incident upon the surface of the pixel. Second, the geometric arrangement of a pixel's photodetector with respect to other elements of the pixel structure can influence the pixel's OE since such structural elements can adversely affect the propagation of light from the pixel surface to the photodetector if not properly configured. The latter is particularly true with regard to CMOS image sensors, which typically include active components, such as reset and access transistors and related interconnecting circuitry and selection circuitry within each pixel. Some types of CMOS image sensors further include amplification and analog-to-digital conversion circuitry within each pixel.

The above circuitry included in CMOS image sensors effectively reduces the actual area of the CMOS pixel that gathers photons. A pixel's fill factor is typically defined as a ratio of the light sensitive area to the total area of a pixel. A domed surface microlens comprising a dielectric material is commonly deposited over a pixel to redirect incident light upon the pixel toward the photodetector. The surface microlens deposited over the pixel can improve light sensitivity and increase a pixel's fill factor. In addition, a surface microlens deposited over the pixel can focus the photons into a smaller area on the photosensitive area of the photodetector which improves spatial resolution and color fidelity.

For economic and performance reasons, the pixels in CMOS image sensors are scaling to smaller and smaller technology feature sizes with more circuitry integrated into the CMOS image sensors. The additional circuitry can lead to decreases in the fill factor of a pixel. In addition, smaller technology feature sizes result in correspondingly smaller surface microlenses deposited over the pixels. Smaller feature size surface microlenses tend to have a more curved microlens surface. The more curved microlens surface over-powers the lens and results in undesirable greater spatial spread at the photosensitive area of the photodetector.

A number of methods have been attempted to achieve a larger fill factor and smaller spatial spread at the photosensitive area of the photodetector, such as varying microlens material, radius of curvature of a microlens, and layer thickness.

For these and other reasons, there is a need for the present invention.

### SUMMARY

One aspect, the present invention provides a pixel including a surface configured to receive incident light. The pixel includes a floor formed by a semiconductor substrate and a photodetector disposed in the floor. The pixel includes a dielectric structure disposed between the surface and the floor. A volume of the dielectric structure between the surface and the photodetector provides an optical path configured to transmit a portion of the incident light upon the surface to the photodetector. The pixel includes an embedded optical element disposed at least partially within the optical path and configured to partially define the optical path.

### BRIEF DESCRIPTION OF THE DRAWINGS

Embodiments of the invention are better understood with reference to the following drawings. The elements of the drawings are not necessarily to scale relative to each other. Like reference numerals designate corresponding similar parts.

FIG. 1 is a block diagram illustrating generally one embodiment of an image sensor.

FIG. 2A is a block and schematic diagram illustrating generally one embodiment of an active pixel sensor.

FIG. 2B illustrates an example layout of the active pixel sensor of FIG. 2A.

FIG. 3 is an illustrative example of a cross section through a substantially ideal model of a pixel with a surface microlens.

FIG. 4 is an illustrative example of a cross section through a conventional CMOS pixel with an under-powered surface microlens.

FIG. 5 is an illustrative example of a cross section through a conventional CMOS pixel with an over-powered surface microlens.

FIG. 6 is an illustrative example of a cross section through one embodiment of a CMOS pixel having an embedded microlens and a surface microlens.

FIG. 7 is an illustrative example of a cross section through one embodiment of a CMOS pixel having an embedded microlens and a surface microlens.

FIG. 8 is an illustrative example of a cross section through one embodiment of a CMOS pixel having an embedded microlens and a surface microlens.

FIG. 9 is an illustrative example of a cross section through one embodiment of a CMOS pixel having an embedded microlens.

FIG. 10 is an illustrative example of a cross section through one embodiment of a CMOS pixel having an embedded microlens and embedded optical obscuration elements or apertures.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following Detailed Description, therefore, is not to be taken in a limiting sense, and the scope of the present invention is defined by the appended claims.

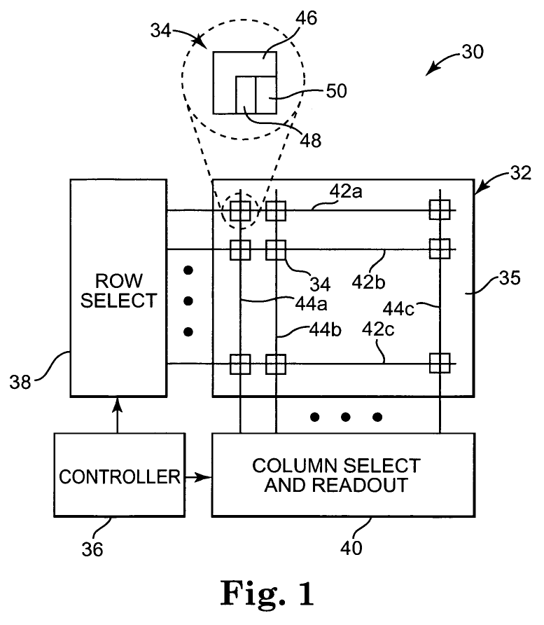

FIG. 1 is a block diagram illustrating generally one embodiment of a complementary metal oxide semiconductor (CMOS) active pixel image sensor (APS) 30 including a focal plane pixel array 32 of pixels 34 formed on a silicon substrate 35. APS 30 includes controller 36, row select circuit 38, and column select and readout circuit 40. Pixel array 32 is arranged in a plurality of rows and columns, with each row of pixels 34 coupled to row select circuit 38 via row signal buses 42 and each column of pixels 34 coupled to column select and readout circuit 40 via output lines 44. As illustrated generally in FIG. 1, each pixel 34 includes a photodetector 46, a charge transfer section 48, and a readout circuit 50. Photodetector 46 comprises a photon-to-electron converter element for converting incident photons to electrons such as, for example, a photodiode or a photogate.

CMOS image sensor 30 is operated by controller 36, which controls readout of charges accumulated by pixels 34 during an integration period by respectively selecting and activating appropriate row signal lines 42 and output lines 44 via row select circuit 38 and column select and readout circuit 40. Typically, the readout of pixels 34 is carried out one row at a time. In this regard, all pixels 34 of a selected row are simultaneously activated by its corresponding row signal line 42, and the accumulated charges of pixels 34 from the activated row read by column select and readout circuit 40 by activating output lines 44.

In one embodiment of APS 30, pixels 34 have substantially uniform pixel size across pixel array 32. In one embodiment of APS 30, pixels 34 vary in pixel size across pixel array 32. In one embodiment of APS 30, pixels 34 have substantially uniform pixel pitch across pixel array 32. In one embodiment of APS 30, pixels 34 have a varying pixel pitch across pixel array 32. In one embodiment of APS 30, pixels 34 have substantially uniform pixel depth across pixel array 32. In one embodiment of APS 30, pixels 34 have varying pixel depth across pixel array 32.

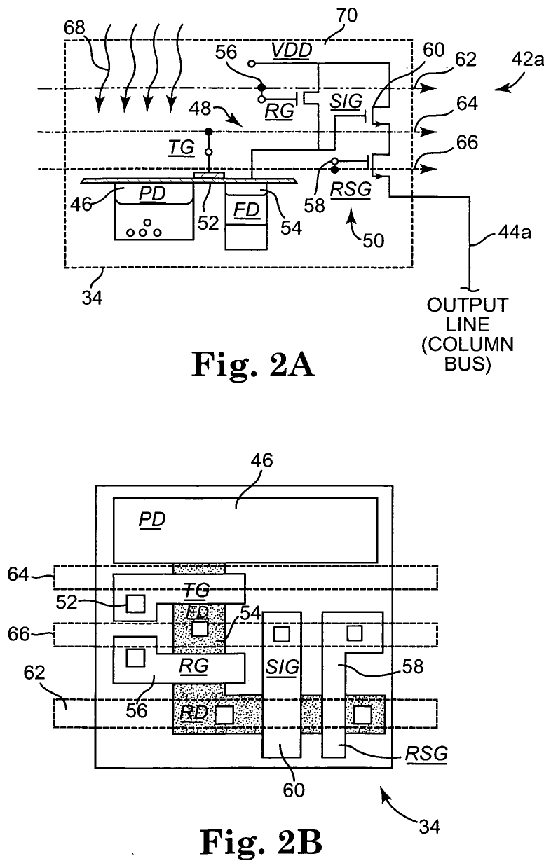

FIG. 2A is a block and schematic diagram illustrating generally one embodiment of a pixel, such as pixel 34 of FIG. 1, coupled in an APS, such as APS 30 of FIG. 1. Pixel 34 includes photodetector 46, charge transfer section 48, and readout circuit 50. Charge transfer section 48 further includes a transfer gate 52 (sometimes referred to as an access transistor), a floating diffusion region 54, and a reset transistor 56. Readout circuit 50 further includes a row select transistor 58 and a source follower transistor 60.

Controller 36 causes pixel 34 to operate in two modes, integration and readout, by providing reset, access, and row select signals via row signal bus 42a which, as illustrated, comprises a separate reset signal bus 62, access signal bus 64, and row select signal bus 66. Although only one pixel 34 is illustrated, row signal buses 62, 64, and 66 extend across all pixels of a given row, and each row of pixels 34 of image sensor 30 has its own corresponding set of row signal buses 62, 64, and 66. Pixel 34 is initially in a reset state, with transfer gate 52 and reset gate 56 turned on. To begin integrating, reset transistor 56 and transfer gate 52 are turned off. During the integration period, photodetector 46 accumulates a photo-generated charge that is proportional to the portion of photon flux 62 incident upon pixel 34 that propagates internally through portions of pixel 34 and is incident upon photodetector 46. The amount of charge accumulated is representative of the intensity of light striking photodetector 46.

After pixel 34 has integrated for a desired period, row select transistor 58 is turned on and floating diffusion region 54 is reset to a level approximately equal to VDD 70 via control of reset transistor 56. The reset level is then sampled by column select and readout circuit 40 via source-follower transistor 60 and output line 44a. Subsequently, transfer gate 52 is turned on and the accumulated charge is transferred from photodetector 42 to floating diffusion region 54. The charge transfer causes the potential of floating diffusion region 54 to deviate from its reset value, approximately VDD 70, to a signal value which is dictated by the accumulated photogenerated charge. The signal value is then sampled by column select and readout circuit 40 via source-follower transistor 60 and output line 44a. The difference between the signal value and reset value is proportional to the intensity of the light incident upon photodetector 46 and constitutes an image signal.

FIG. 2B is an illustrative example of a layout of pixel 34 illustrated by FIG. 2A. Pixel control elements (e.g., reset transistor 56, row select transistor 58, source-follower transistor 60) and related interconnect circuitry (e.g., signal buses 62, 64, 66 and related transistor connections) are generally implemented in metallic layers that overlay a silicon substrate in which photodetector 46 is located. Although other layout designs are possible, it is evident that the pixel control elements and related interconnect circuitry consume a great deal of space within pixel 34 regardless of the layout design. Such space consumption is even greater in digital pixel sensors (DPS's), which include analog-to-digital converter circuitry within each pixel.

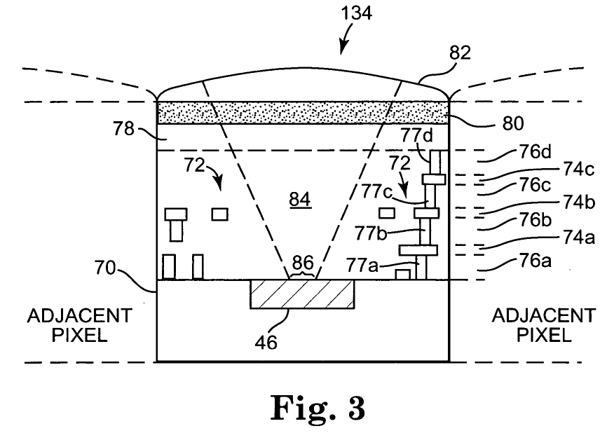

FIG. 3 is an illustrative example of a cross section through a substantially ideal model of a CMOS pixel 134. Photodetector 46 is disposed in a silicon (Si) substrate 70 that forms the pixel floor. Pixel control elements and related interconnect circuitry are illustrated generally at 72 and are disposed in multiple metal layers 74 separated by multiple dielectric insulation layers (e.g., silicon dioxide (SiO₂) or other suitable dielectric material) 76. Vertical interconnect stubs or vias 77 electrically connect elements located in different metal layers 74. A dielectric passivation layer 78 is disposed over the alternating metal layers 74 and dielectric insulation layers 76. A color filter layer 80 (e.g., red, green, or blue of a Bayer pattern, which is described below) comprising a resist material is disposed over passivation layer 78.

To improve light sensitivity, a domed surface microlens 82 comprising a suitable material having an index of refraction greater than one (e.g., a photo resist material, other suitable organic material, or silicon dioxide (SiO₂)) is deposited over the pixel to redirect incident light upon the pixel toward photodetector 46. Surface microlens 82 has a convex structure having positive optical power. Surface microlens 82 can effectively increase a pixel's fill factor, which is typically defined as a ratio of the light sensitive area to the total area of a pixel, by improving the angles at which incident photons strike the photodetector. In the substantially ideal model illustrated in FIG. 3, surface microlens 82 can effectively focus the photons into a small as possible photosensitive area, indicated at 86, of photodetector 46 which reduces spatial spread at the photosensitive area of photodetector 46.

Together, the above described elements of the pixel are hereinafter collectively referred to as the pixel structure. As previously described, the light sensitivity of a pixel is influenced by the geometric arrangement of the photodetector with respect to other elements of the pixel structure, as such structure can affect the propagation of light from the surface of the pixel to the photodetector (i.e., the optical efficiency (OE)). In fact, the size and shape of the photodetector, the distance from the photodetector to the pixel's surface, and the arrangement of the control and interconnect circuitry relative to the photodetector can all impact a pixel's OE.

Conventionally, in efforts to maximize pixel light sensitivity, image sensor designers have typically defined an optical path 84, or light cone, between the photodetector and microlens which is based on geometrical optics. Optical path 84 typically comprises only the dielectric passivation layer 78 and multiple dielectric insulation layers 76. Although illustrated as being conical in nature, the optical path 84 may have suitable other forms as well. However, regardless of the form of optical path 84, as technology scales to smaller feature sizes, such an approach becomes increasingly difficult to implement, and the effect of a pixel's structure on the propagation of light is likely to increase.

Optical path 84 illustrated in FIG. 3 represents a substantially ideal optical path in pixel 134. Surface microlens 82 is substantially matched to the pixel optics of pixel 134, such that surface microlens 82 has a high light collection power which contributes to a large fill factor and high sensitivity. In addition, as illustrated in FIG. 3, in this idealized scenario, the photons are focused by surface microlens 82 along optical path 84 onto a small as possible photosensitive area, indicated at 86, of photodetector 46 which results in a minimum spatial spread. The minimal spatial spread improves spatial resolution and color fidelity. However, the ideal situation illustrated in FIG. 3 is not typically obtainable with a conventional surface microlens especially as CMOS pixel technology scales to smaller and smaller feature sizes with more and more circuitry contained within the pixels.

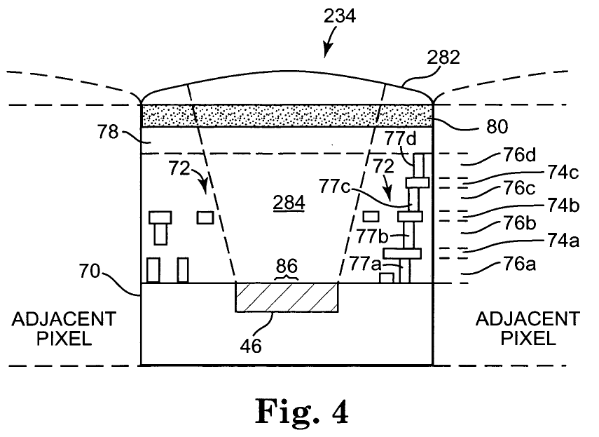

FIG. 4 is an illustrative example of a cross section through a conventional CMOS pixel 234. CMOS pixel 234 is similar to the above-described CMOS pixel 134 except CMOS pixel 234 includes a domed surface microlens 282 deposited over the pixel to redirect incident light upon the pixel towards photodetector 46. Surface microlens 282 has a convex structure having positive optical power. Unlike surface microlens 82 which is matched to the pixel optics of pixel 134, surface microlens 282 is an under-powered surface microlens. The under-powered surface microlens 282 results in a non-ideal optical path 284 which has a focal point which is too far beyond the photosensitive area of photodetector 46. This results in an increased spatial spread at the photosensitive area of photodetector 46 (i.e., the photons in optical path 284 strike a larger area of photodetector 46 than the desired small photosensitive area indicated at 86). The increased spatial spread degrades the spatial resolution and color fidelity of pixel 234.

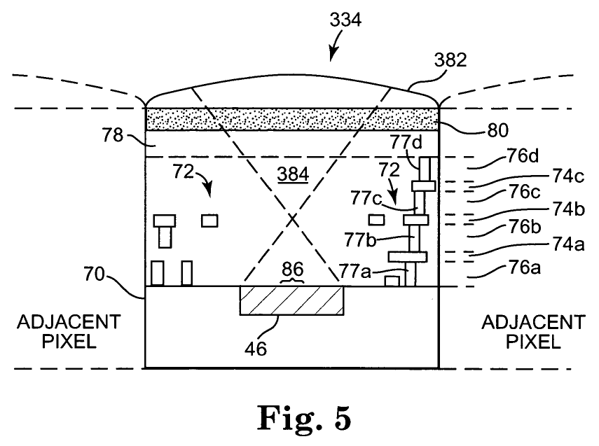

FIG. 5 is an illustrative example of a cross section through a conventional CMOS pixel 334. CMOS pixel 334 is similar to the above-described CMOS pixel 134 except CMOS pixel 334 includes a domed surface microlens 382 deposited over the pixel to redirect incident light upon the pixel towards the photodetector 46. Surface microlens 382 has a convex structure having positive optical power. Unlike surface microlens 82 which is matched to the pixel optics of pixel 134, surface microlens 382 is an over-powered surface microlens.

As discussed in the Background, as image sensors are scaling to smaller and smaller technology feature sizes, the surface microlens tends to have a more curved microlens surface, which typically results in an over-powered surface microlens which is illustrated by surface microlens 382 of pixel 334. As illustrated in FIG. 5, surface microlens 382 causes optical path 384 to be non-ideal with a focal point prior to the photosensitive area of photodetector 46. Thus, the light in optical path 384 is no longer converging, but instead is spreading as it hits the photosensitive area of photodetector 46 which increases the spatial spread at the photosensitive area of photodetector 46 (i.e., the photons in the optical path 384 strike a larger area of photodetector 46 than the desired small photosensitive area indicated at 86). The increased spatial spread degrades spatial resolution and color fidelity of pixel 334.

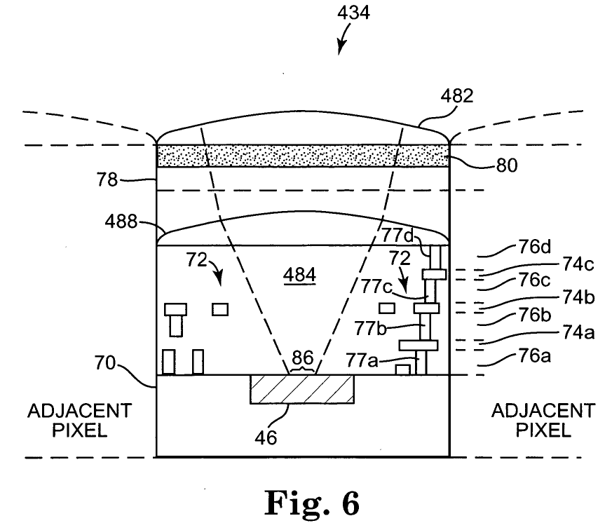

FIG. 6 is an illustrative example of a cross section through a CMOS pixel 434 according to one embodiment of the present invention. Photodetector 46 is disposed in a silicon (Si) substrate 70 that forms the pixel floor. Pixel control elements and related interconnect circuitry are illustrated generally at 72 and are disposed in multiple metal layers separated by multiple dielectric insulation layers (e.g., silicon dioxide (SiO₂) or other suitable dielectric material) 76. Vertical interconnects stubs or vias 77 electrically connect elements located in different metal layers 74.

An embedded microlens 488 is formed over the alternating metal layers 74 and dielectric insulation layers 76. Embedded microlens 488 has a convex structure having positive optical power. A dielectric passivation layer 78 is disposed over embedded microlens 488. A color filter layer 80 (e.g., red, green, or blue of a Bayer pattern, which is described below) comprising a resist material is disposed over passivation layer 78. A domed surface microlens 482 comprising a suitable material having an index of refraction greater than one (e.g., a photo resist material, other suitable organic material, or silicon dioxide (SiO₂)) deposited over pixel 434 to redirect incident light upon the pixel towards photodetector 46. Surface microlens 482 has a convex structure having positive optical power.

Embedded microlens 488 comprises a suitable material having an index of refraction greater than one. In one embodiment, embedded microlens 488 comprises a material having a relatively high index of refraction (e.g., silicon nitride (Si₃N₄) or other suitable material having a relatively high index of refraction). In one embodiment, embedded microlens 488 is formed by depositing a film of silicon nitride over the alternating metal layers 74 and dielectric insulation layers 76, such as with a chemical vapor deposition process. After the silicon nitride film is deposited it is etched to form the embedded microlens 488 convex structure.

Embedded microlens 488 redirects light provided from surface microlens 482 to better focus the photons into a small as possible photosensitive area, indicated at 86, of photodetector 46 which reduces spatial spread at the photosensitive area of photodetector 46. Embedded microlens 488 can also effectively increase the fill factor of pixel 434 by improving the angles at which incident photons strike photodetector 46.

As illustrated in FIG. 6, surface microlens 482 would be an under-powered surface microlens similar to microlens 282 illustrated in FIG. 4, however, pixel 434 includes embedded microlens 488 having positive optical power which operates with microlens 482 having positive optical power to achieve a more ideal optical path 484 which substantially matches the pixel optics of pixel 434. By operating together, surface microlens 482 and embedded microlens 488 have a high light collection power which contributes to a large fill factor and high sensitivity. In addition, as illustrated in FIG. 6, the photons are focused by surface microlens 482 and further focused by embedded microlens 488 along optical path 484 onto a small as possible photosensitive area, indicated at 86, of photodetector 46 which results in minimal spatial spread. The minimal spatial spread improves spatial resolution and color fidelity of pixel 434.

Embedded microlens 488 is embedded into the layers which form CMOS pixel 434. As a result, embedded microlens 488 is compatible with existing CMOS process technologies and more easily scales with the decreasing technology feature sizes.

In addition, the addition of microlens 488 in combination with surface microlens 482 can provide additional flexibility to the image sensor design and the image sensor fabrication process.

One example embodiment of pixel 434 with embedded microlens 488 achieved an approximately 20-30% improvement in OE as compared to a substantially similar pixel which did not include an embedded microlens, but included a surface microlens.

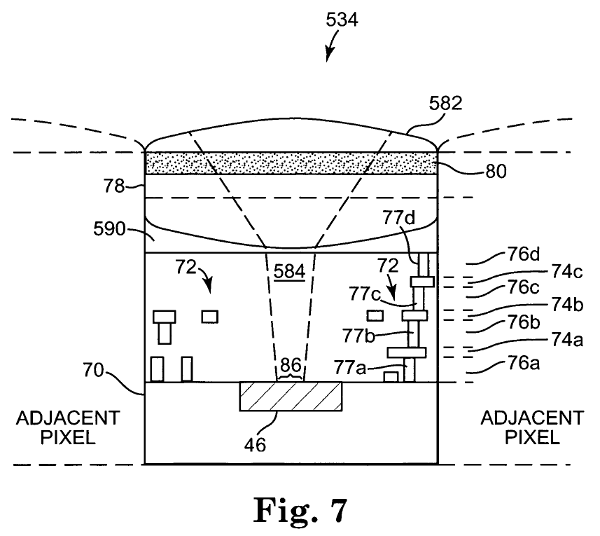

FIG. 7 is an illustrative example of cross section through a CMOS pixel 534 according to one embodiment of the present invention. The structure of CMOS pixel 534 is similar to the above-described structure of CMOS pixel 434. CMOS pixel 534 includes an embedded microlens 590 formed over the alternating metal layers 74 and dielectric insulation layer 76. Instead of the convex structure of embedded microlens 488, embedded microlens 590 has a concave structure having negative optical power. A dielectric passivation layer 78 is disposed over embedded microlens 590. A color filter layer 80 comprising a resist material is disposed over passivation layer 78. A domed surface microlens 582 comprising a suitable material having an index of refraction greater than one is deposited over pixel 534 to redirect incident light upon the pixel towards photodetector 46. Surface microlens 582 has a convex structure having positive optical power.

Embedded microlens 590 comprises a suitable material having an index of refraction greater than one. In one embodiment, embedded microlens 590 comprises a material having a relatively high index of refraction (e.g., silicon nitride (Si₃N₄) or other suitable material having a relatively high index of refraction). In one embodiment, embedded microlens 590 is formed by depositing a film of silicon nitride over the alternating metal layers 74 and dielectric insulation layers 76, such as with a chemical vapor deposition process. After the silicon nitride film is deposited it is etched to form the embedded microlens 590 structure.

Embedded microlens 590 redirects light provided from surface microlens 582 to better focus the photons into a small as possible photosensitive area, indicated at 86, a photodetector 46 which reduces spatial spread at the photosensitive area of photodetector 46. Embedded microlens 590 can also effectively increase the fill factor of pixel 534 by improving the angles at which incident photons strike photodetector 46.

As illustrated in FIG. 7, surface microlens 582 would be an over-powered surface microlens similar to microlens 382 illustrated in FIG. 5, however, pixel 534 includes embedded microlens 590 having negative optical power which operates with microlens 582 having positive optical power to achieve a more ideal optical path 584 which substantially matches the pixel optics of pixel 534. By operating together, surface microlens 582 and embedded microlens 590 have a high light collection power which contributes to a large fill factor and high sensitivity. In addition, as illustrated in FIG. 7, the photons which would otherwise be overly focused by surface microlens 582 are redirected by embedded microlens 590 along optical path 584 onto a small as possible photosensitive area, indicated at 86, of photodetector 46 which results in a minimal spatial spread. The minimal spatial spread improves spatial resolution and color fidelity of pixel 534.

Embedded microlens 590 is embedded into the layers which form CMOS pixel 534. As a result, embedded microlens 590 is compatible with existing CMOS process technologies and more easily scales with the decreasing technology feature sizes.

In addition, the addition of microlens 590 in combination with surface microlens 582 can provide additional flexibility to the image sensor design and the image sensor fabrication process.

In pixel 434 illustrated in FIG. 6 and pixel 534 illustrated in FIG. 7, a color filter layer 80 is disposed over a passivation layer 78. Thus, in pixel 434, color filter layer 80 filters light redirected by service microlens 482 prior to the light reaching embedded microlens 488 along optical path 484. Similarly, in pixel 534, color filter layer 80 filters light redirected by surface microlens 582 prior to the light reaching embedded microlens 590 along optical path 584.

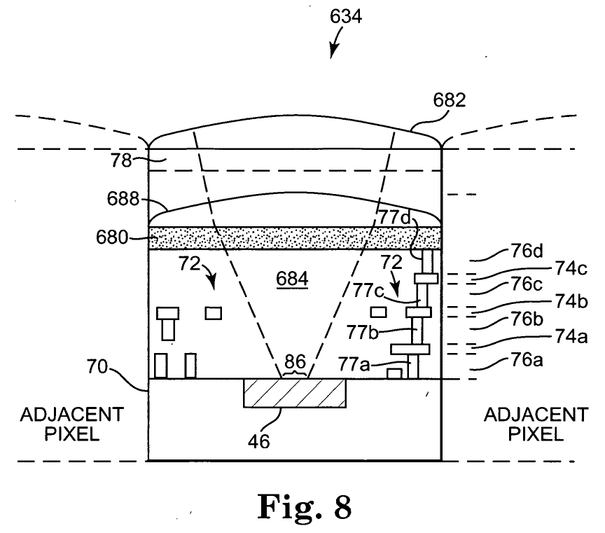

FIG. 8 is an illustrative example of a cross section through a CMOS pixel 634 according to one embodiment of the present invention. The structure of CMOS pixel 634 is similar to the above-described structure of CMOS pixel 434. A color filter layer 680 (e.g., red, green, or blue of a Bayer pattern, which is described below) comprising a resist material is disposed over the alternating metal layers 74 and dielectric insulation layers 76. An embedded microlens 688 is formed over the color filter layer 680. Embedded microlens 688 has a convex structure having positive optical power. A dielectric passivation layer 78 is disposed over embedded microlens 688. A domed surface microlens 682 comprising a suitable material having an index of refraction greater than one is deposited over pixel 634 to redirect incident light upon the pixel towards photodetector 46. Surface microlens 682 has a convex structure having positive optical power.

Embedded microlens 688 comprises a suitable material having an index of refraction greater than one. In one embodiment, embedded microlens 688 comprises a material having a relatively high index of refraction (e.g., silicon nitride (Si₃N₄) or other suitable material having a relatively high index of refraction). In one embodiment, embedded microlens 688 is formed by depositing a film of silicon nitride over color filter layer 680, such as with a chemical vapor deposition process. After the silicon nitride film is deposited it is etched to form the embedded microlens 688 structure.

Embedded microlens 688 redirects light provided from surface microlens 682 to better focus the photons into a small as possible photosensitive area, indicated at 86, a photodetector 46 similar to as described above for embedded microlens 488 of pixel 434. Unlike pixel 434, pixel 634 includes color filter layer 680 which filters light after it has been redirected by embedded microlens 688 along optical path 684.

As illustrated in FIG. 8, surface microlens 682 would be an under-powered surface microlens similar to microlens 282 illustrated in FIG. 4, however, pixel 634 includes embedded microlens 688 having positive optical power which operates with microlens 682 having positive optical power to achieve a more ideal optical path 684 which substantially matches the pixel optics of pixel 634. By operating together, surface microlens 682 and embedded microlens 688 have a high light collection power which contributes to a large fill factor and high sensitivity. In addition, as illustrated in FIG. 8, the photons are focused by surface microlens 682 and further focused by embedded microlens 688 along optical path 684 onto a small as possible photosensitive area, indicated at 86, of photodetector 46 which results in a minimal spatial spread. The minimal spatial spread improves spatial resolution and color fidelity of pixel 634.

In pixels 434 and 534, a color filter layer 80 is located prior to the embedded microlens along the optical path. In pixel 634 illustrated in FIG. 8, color filter layer 680 is located after embedded microlens 688 along optical path 684. In another embodiment of a pixel according to the present invention, a color filter is integrated into an embedded optical element, such as an embedded color filtering microlens.

Embedded microlens 688 is embedded into the layers which form CMOS pixel 634. As a result, embedded microlens 688 is compatible with existing CMOS process technologies and more easily scales with the decreasing technology feature sizes.

In addition, the addition of microlens 688 in combination with surface microlens 682 can provide additional flexibility to the image sensor design and the image sensor fabrication process.

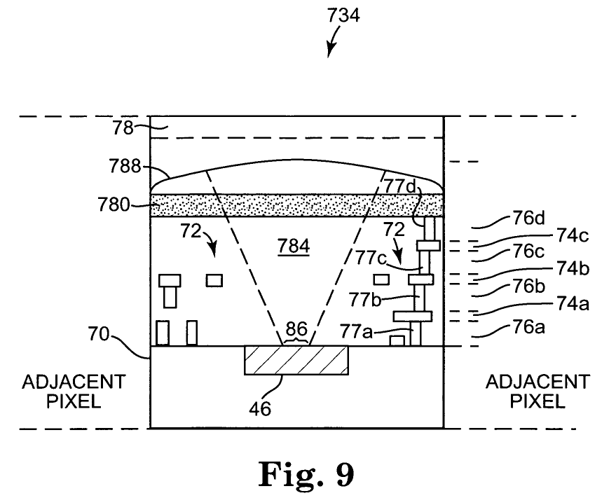

FIG. 9 is an illustrative example of a cross section through a CMOS pixel 734 according to one embodiment of the present invention. The structure of CMOS pixel 734 is similar to the structure of CMOS pixel 634. However, CMOS pixel 734 does not include a surface microlens.

A color filter layer 780 (e.g., red, green, or blue of a Bayer pattern, which is described below) comprising a resist material is disposed over the alternating metal layers 74 and dielectric insulation layer 76. An embedded microlens 788 is formed over color filter layer 780. Embedded microlens 788 has a convex structure having positive optical power. A dielectric passivation layer 78 is disposed over embedded microlens 788.

Embedded microlens 788 comprises a suitable material having an index of refraction greater than one. In one embodiment, embedded microlens 788 comprises a material having a relatively high index of refraction (e.g., silicon nitride (Si₃N₄) or other suitable material having a relatively high index of refraction). In one embodiment, embedded microlens 788 is formed by depositing a film of silicon nitride over color filter layer 780, such as with a chemical vapor deposition process. After the silicon nitride film is deposited it is etched to form the embedded microlens 788 structure.

Depending on specific process implementations, this type of deposition and etching process can yield lower cost and higher index of refraction embedded microlenses, such as embedded microlenses 488, 590, 688, and 788, as compared to surface microlenses, such as surface microlenses 482, 582, and 682. Surface microlenses are typically spun on the silicon wafer and the film that forms the surface microlens has solvents that allow the surface microlens film to essentially float across the wafer during the formation process. At some point in the typical process, this liquid solvent is baked off. In addition, surface microlenses are typically coated, because the surface microlens is at the surface of the pixel. Depending on specific process implementations, these processes which are used to form surface microlenses can be more expensive and result in lenses which have lower indexes of refraction.

Embedded microlens 788 is embedded into the layers which form CMOS pixel 734. As a result, embedded microlens 788 is compatible with existing CMOS process technologies and more easily scales with the decreasing technology feature sizes.

Embedded microlens 788 redirects incident light upon pixel 734 toward photodetector 46. Embedded microlens 788 focuses the photons into a small as possible photosensitive area, indicated at 86, a photodetector 46 to reduce spatial spread at the photosensitive area of photodetector 46. The reduced spatial spread improves spatial resolution and color fidelity of pixel 734. Embedded microlens 788 can also effectively increase fill factor of pixel 734 by improving the angles at which incident photon strike photodetector 46.

As illustrated in FIG. 9, embedded microlens 788 having positive optical power operates to achieve optical path 784 which substantially matches the pixel optics of pixel 734. Embedded microlens 788 preferably has a high light collection power which contributes to large fill factor and high sensitivity.

One example embodiment of pixel 734 with embedded microlens 788 achieved an approximately 50 to 60% improvement in OE as compared to a substantially similar pixel which did not include an embedded microlens. The improvement in OE increases as the pixel size is reduced to correspond to smaller technology feature sizes.

An embedded microlens, such as microlenses 488, 590, 688, and 788, can improve OE of a pixel as described above. In addition, an embedded microlens can be employed to improve and/or optimize other specific objective, or measurable, criteria associated with pixel performance. Some example OE-dependent pixel performance criteria, which can be improved and/or optimized via an embedded microlens, include pixel response, pixel color response (e.g., red, green, or blue response), and pixel cross-talk.

Pixel response is defined as the amount of charge integrated by a pixel's photodetector during a defined integration period. Pixel response can be improved with an embedded microlens, such as microlenses 488, 590, 688, and 788.

Pixel arrays of color image sensors, such as pixel array 32 illustrated in FIG. 1, are often typically configured such that each pixel of the array is assigned to sense a separate primary color. Such an assignment is made by placing a color filter array over the pixel array, with each pixel having an associated color filter corresponding to its assigned primary color. Examples of such color filters include: the color filter layers 80 of pixels 134, 234, 334, 434, and 534; color filter layer 680 of pixel 634; and color filter layer 780 of pixel 734. As light passes through the color filter, only wavelengths of the assigned primary color pass through. Many color filter arrays have been developed, but one commonly used color filter array is the Bayer pattern. The Bayer pattern employs alternating rows of red pixels wedged between green pixels, and blue pixels wedged between green pixels. As such, the Bayer pattern has twice as many green pixels as red pixels or blue pixels. The Bayer pattern takes advantage of the human eye's predilection to see green illuminance as the strongest influence in defining sharpness, and a pixel array employing the Bayer pattern provides substantially equal image sensing response whether the array is orientated horizontally or vertically.

When laying out a pixel that is configured to sense a certain wavelength or range of wavelengths, such as a pixel comprising a portion of a pixel array arranged according to the Bayer pattern which is assigned to sense green, blue, or red, it is beneficial to be able to optimize the pixel's response to its assigned color (i.e., color response). An embedded microlens, such as embedded microlenses 488, 590, 688, and 788, can improve the pixel's color response.

In a color image sensor, the term pixel cross-talk generally refers to a portion or amount of a pixel's response that is attributable to light incident upon the pixel's photodetector that has a color (i.e., wavelength) other than the pixel's assigned color. Such cross-talk is undesirable as it distorts the amount of charge collected by the pixel in response to its assigned color. For example, light from the red and/or blue portion of the visible spectrum that impacts the photodetector of a green pixel will cause the pixel to collect a charge that is higher than would otherwise be collected if only light from the green portion of the visible spectrum impacted the photodetector. Such cross-talk can produce distortions, or artifacts, and thus reduce the quality of a sensed image. Cross-talk can be substantially reduced with an embedded microlens, such as microlenses 488, 590, 688, and 788.

The above-described embedded microlenses 488, 590, 688, and 788 are embodiments of an embedded optical element. Other suitable embedded optical elements other than microlenses can be embedded in a pixel according to embodiments of the present invention to partially define the optical path within the pixel. For example, the above-described embedded microlenses 488, 590, 688, and 788 are rotational symmetric. Another embodiment of a pixel can include an embedded optical element which is rotational asymmetric, such as a prism.

In some embodiments, the embedded optical elements have a convex structure having positive optical power, such as embedded microlenses 488, 688, and 788. In some embodiments, the embedded optical elements have a concave structure having negative optical power, such as embedded microlens 590. In some embodiments, the embedded optical elements have a substantially flat structure having substantially no optical power. In some embodiments, the embedded optical elements have a saddle structure having combination optical power.

In one embodiment of an APS having pixels with embedded optical elements, the embedded optical elements have substantially uniform optical power across the pixel array. In one embodiment of an APS having pixels with embedded optical elements, the embedded optical elements have varying optical power across the pixel array. The varying optical power can be achieved, for example, by varying curvatures of the structure of the embedded optical elements and/or varying the material that forms the embedded optical elements.

The above-described embedded optical elements (e.g., embedded microlenses 488, 590, 688, and 788) have a spherical geometric structure. Other embodiments of the embedded optical elements have an aspherical geometric structure.

In one embodiment of an APS having pixels with embedded optical elements, the embedded optical elements have substantially uniform geometric structure across the pixel array. In one embodiment of an APS having pixels with embedded optical elements, the embedded optical elements have varying geometric structure across the pixel array. Examples of types of geometric structure of the embedded optical elements which can be varied across the pixel array include the size of the embedded optical elements, the thickness of the embedded optical elements, and the curvature of the embedded optical elements.

The above-described embedded microlenses 488, 590, and 688 respectively have their optical axis collinear with the optical axis of the corresponding surface microlenses 482, 582, and 682. Pixels according to the present invention are not limited to this alignment and configuration. For example, one embodiment of a pixel according to the present invention includes an embedded optical element that has its optical axis tilted with respect to the optical axis of a corresponding surface microlens. In one embodiment of a pixel, the pixel includes an embedded optical element having its optical axis decentered from the optical axis of a corresponding surface microlens.

In one embodiment of an APS having pixels with embedded optical elements, the embedded optical elements have substantially uniform shift (i.e., decentering) at varying angles of incident across the pixel array. In one embodiment of an APS having pixels with embedded optical elements, the embedded optical elements have varying shift (i.e., decentering) at varying angles of incident across the pixel array. In one embodiment of an APS having pixels with embedded optical elements, the embedded optical elements have a substantially uniform tilt at varying angles of incident across the pixel array. In one embodiment of an APS having pixels with embedded optical elements, the embedded optical elements have varying tilt at varying angles of incident across the pixel array.

In one embodiment of an APS having pixels with embedded optical elements, the pixels have a substantially uniform pixel pitch across the pixel array. In one embodiment of an APS having pixels with embedded optical elements, the pixels have a varying pixel pitch across the pixel array.

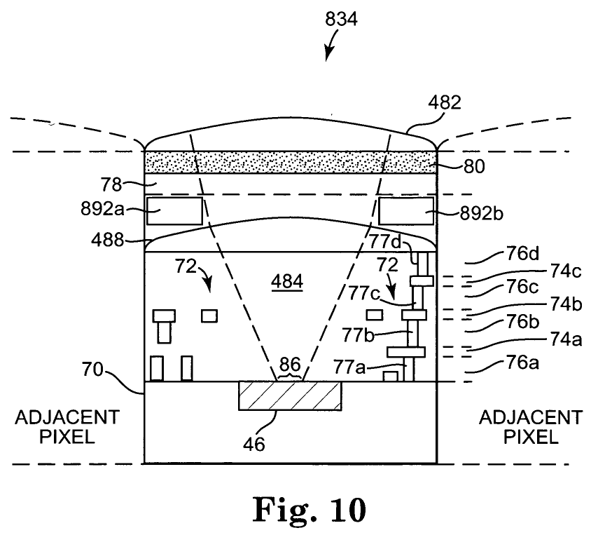

FIG. 10 is an illustrative example of a cross section through a CMOS pixel 834 according to one embodiment of the present invention. The structure of CMOS pixel 834 is substantially similar to the structure of CMOS pixel 434, except pixel 834 includes embedded optical elements 892. Embedded optical elements 892 are optical obscuration elements or apertures which block undesired light. In one embodiment, embedded optical elements 892 are absorptive. In one embodiment, embedded optical elements 892 are reflective. In one embodiment, embedded optical elements 892 are spectrally selective.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A pixel comprising:
a surface configured to receive incident light;
a floor formed by a semiconductor substrate;
a photodetector disposed in the floor;
a dielectric structure disposed between the surface and the floor, wherein a volume of the dielectric structure between the surface and the photodetector provides an optical path configured to transmit a portion of the incident light upon the surface to the photodetector; and
an embedded optical element disposed at least partially within the optical path and configured to partially define the optical path.

2. The pixel of claim 1 wherein the embedded optical element is structured to increase the portion of incident light transmitted to the photodetector via the optical path.

3. The pixel of claim 1 wherein the embedded optical element comprises an embedded lens.

4. The pixel of claim 1 wherein the embedded optical element is selected from a group consisting of:
a rotational symmetric optical element; and
a rotational asymmetric optical element.

5. The pixel of claim 1 wherein the embedded optical element is selected from a group consisting of:
an optical element having a spherical geometric structure; and
an optical element having a aspherical geometric structure.

6. The pixel of claim 1 comprising:
an embedded optical obscuration element configured to block undesired light.

7. The pixel of claim 6 wherein the optical obscuration element is selected from a group consisting of:
an absorptive optical element;
a reflective optical element; and
a spectrally selective optical element.

8. The pixel of claim 1 comprising:
a surface lens formed over the surface and configured to receive the incident light and redirect the incident light to the embedded optical element.

9. The pixel of claim 8 wherein the embedded optical element has an optical axis selected from a group consisting of:
an optical axis collinear with an optical axis of the surface lens;
an optical axis tilted with respect to an optical axis of the surface lens; and
an optical axis decentered from an optical axis of the surface lens.

10. The pixel of claim 1 comprising:
a color filter selected from a group consisting of:
a color filter disposed within the optical path between the surface and the embedded optical element;
a color filter disposed within the optical path between the embedded optical element and the photodetector; and
a color filter integrated into the embedded optical element.

11. The pixel of claim 1 wherein the embedded optical element is selected from a group consisting of:
an optical element having a convex structure having positive optical power;
an optical element having a concave structure having negative optical power;
an optical element having a substantially flat structure having substantially no optical power; and
an optical element having a saddle structure having combination optical power.

12. The pixel of claim 1 wherein the pixel is a complementary metal oxide semiconductor (CMOS) pixel.

13. An image sensor comprising:
an array of pixels, each pixel comprising:
a photodetector;
a dielectric positioned between light incident upon the pixel and the photodetector; and
an embedded lens disposed in the dielectric and configured to redirect a portion of the light incident upon the pixel to the photodetector.

14. The image sensor of claim 13 wherein each pixel comprises:
a surface lens formed over the dielectric and configured to receive the light incident upon the pixel and redirect the light incident upon the pixel to the embedded lens.

15. The image sensor of claim 13 wherein the array of pixels is selected from a group consisting of:
an array of pixels including pixels having a substantially uniform pixel pitch across the pixel array; and
an array of pixels including pixels having a varying pixel pitch across the pixel array.

16. The image sensor of claim 13 wherein the array of pixels is selected from a group consisting of:
an array of pixels including pixels having embedded lenses with substantially uniform shift at varying angles of incident across the pixel array; and
an array of pixels including pixels having embedded lenses with varying shift at varying angles of incident across the pixel array.

17. The image sensor of claim 13 wherein the array of pixels is selected from a group consisting of:
an array of pixels including pixels having embedded lenses with substantially uniform tilt at varying angles of incident across the pixel array; and
an array of pixels including pixels having embedded lenses with varying tilt at varying angles of incident across the pixel array.

18. The image sensor of claim 13 wherein the array of pixels is selected from a group consisting of:
an array of pixels including pixels having embedded lenses with substantially uniform geometric structure across the pixel array; and
an array of pixels including pixels having embedded lenses with varying geometric structure across the pixel array.

19. The image sensor of claim 13 wherein the array of pixels is selected from a group consisting of:
an array of pixels including pixels having embedded lenses with substantially uniform optical power across the pixel array; and
an array of pixels including pixels having embedded lenses with varying optical power across the pixel array.

20. The optical sensor of claim 13 wherein the embedded lens comprises a microlens.

21. A method of operating a semiconductor-based pixel, the method comprising:
receiving incident light via a surface; and
transmitting, within an optical path defined in a dielectric structure disposed between the surface and a photodetector, a portion of the incident light to the photodetector including increasing the portion of incident light transmitted to the photodetector via the optical path with at an embedded optical element disposed at least partially within the optical path.

22. The method of claim 21 wherein the transmitting includes increasing the portion of incident light transmitted to the photodetector via the optical path with an embedded lens.
